(19) United States
(12) Patent Application Publication
(10) Pub. No.: US 2008/0079358 A1
(43) Pub. Date: Apr. 3, 2008

(54) Organic electroluminescent element

(75) Inventor: Tasuku Satou, Kanagawa (JP)

Correspondence Address: BIRCH STEWART KOLASCH & BIRCH, PO BOX 747, FALLS CHURCH, VA, 22040-0747, US

(73) Assignee: FUJIFILM Corporation

(21) Appl. No.: 11/902,459

(22) Filed: Sep. 21, 2007

(30) Foreign Application Priority Data
Sep. 29, 2006 (JP) 2006-269485
Jul. 30, 2007 (JP) 2007-197716

(51) Int. Cl. H01L 51/50; H01J 1/62; H05B 33/14; H05B 33/20

(52) U.S. Cl. 313/504

(57) ABSTRACT

An organic electroluminescent element including at least one organic layer including a light-emitting layer between a pair of electrodes, wherein the light-emitting layer includes a metal complex having a tri-dentate or higher multi-dentate ligand, and a metal-free compound capable of giving a three or higher coordination with the same metal element as a central metal of the metal complex is provided. An organic electroluminescent element having a high light emitting efficiency and excellent durability is provided.

### CROSS-REFERENCE TO RELATED APPLICATION

This application claims priority under 35 USC 119 from Japanese Patent Application Nos. 2006-269,485 and 2007-197,716, the disclosures of which are incorporated by reference herein.

### BACKGROUND OF THE INVENTION

The present invention relates to an organic electroluminescent element (hereinafter, referred to as an “organic EL element” in some cases).

In recent years, research and development concerning various display elements are being actively performed. Particularly, organic electroluminescent (EL) elements are drawing attention as promising display elements, since they can exhibit light emission having high brightness at a low driving voltage.

Recently, in the development of organic EL elements, a variety of research for, for example, lowering driving voltage, improving durability, and improving external quantum efficiency has been performed.

As a technology for allowing light emission at a low driving voltage, the use copper phthalocyanines or amine compounds as a hole injection material has been reported. However, problems arise in such an element employing the hole injection material in that when light emission is continued for a long period of time or the element is left under a high temperature for a long period of time, the brightness may decline or a dark spot (non-luminescent spot) may form.

Japanese Patent Application Laid-Open (JP-A) No. 2003-7476 discloses an organic EL element having a metal porphyrin complex and a metal-free porphyrin compound in a hole injecting layer, as a means for improving driving durability. Each of the metal porphyrin complex and the metal-free porphyrin compound included in the hole injecting layer is a non-luminescent compound, and has an effect of traping a small amount of metal eluted from an anode while an organic EL element is driven for a long time, thereby preventing the element from being deteriorated by the small amount of metal. An improvement in driving durability could be expected, but improvement in light-emitting layer performances, such as improvement in light emitting efficiency, cannot be expected.

In addition, U.S. Pat. Nos. 6,303,238 and 6,653,564 disclose that an element having a phosphorescent material such as an octaethylporphyrin platinum complex exhibits a high external quantum efficiency.

However, the element is not sufficient in light-emitting efficiency even if the phosphorescent material is included therein, and thus higher efficiency has been demanded. Moreover, since the element having a phosphorescent material is not satisfactory in driving durability, further improvement has been demanded.

### SUMMARY OF THE PRESENT INVENTION

The present invention has been made in view of the above circumstances and provides an organic electroluminescent element comprising at least one organic layer including a light-emitting layer between a pair of electrodes, wherein the light-emitting layer includes a metal complex having a tri-dentate or higher multi-dentate ligand, and a metal-free compound capable of giving a three or higher coordination with the same metal element as a central metal of the metal complex.

### DETAILED DESCRIPTION OF THE PRESENT INVENTION

An object of the present invention is to provide an organic electroluminescent element having a high light emitting efficiency and excellent durability.

In the following, the organic electroluminescence element of the present invention will be described in detail.

The organic electroluminescence element according to the present invention has at least one organic compound layer including an organic light-emitting layer (hereinafter, referred simply to as a “light-emitting layer” in some cases) in between a pair of electrodes on a substrate. In view of the nature of an electroluminescence element, it is preferred that at least either electrode of an anode and a cathode is transparent.

The organic compound layer may be constructed by a single layer or a laminated layer of layers. As a lamination pattern of the organic compound layers, it is preferred that the layers are laminated in the order of a positive hole transport layer, a light-emitting layer, and an electron transport layer from the anode side. Moreover, a charge blocking layer or the like between the positive hole transport layer and the light-emitting layer or between the light-emitting layer and the electron transport layer may be provided. In addition, a positive hole injection layer may be provided in between the light-emitting layer and the anode, and similarly, an electron injection layer may be provided in between the cathode and the electron transport layer. Each layer thereof may be constructed by plural secondary layers

1. Multi-Dentate Metal Complex and Metal-Free Compound

A light-emitting layer in the present invention is characterized to include, as a light emitting material, a metal complex having a tri-dentate or higher multi-dentate ligand, and furthermore, includes a metal-free compound (hereinafter, referred simply to as a “non-metal compound” in some cases), which is capable of giving a three or higher coordination with the same metal element as a central metal of the metal complex.

Preferably, the coordination number of the metal-free compound is same as the coordination number of the metal complex. More preferably, the metal-free compound has, as a partial structure, a chemical structure in which metal is removed from the metal complex.

Preferably, the metal-free compound is a linear compound. More preferably, the metal complex is a compound represented by the following formula LA1, and the linear compound is a compound represented by the following formula LA2:

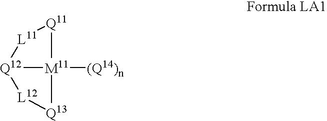

wherein M¹¹ represents a metal ion; Q¹¹ to Q¹⁴ each independently represent a substituent which coordinates with M¹¹; L¹¹ and L¹² each independently represent a single bond or a linking group; and n represents an integer of from 0 to 4,

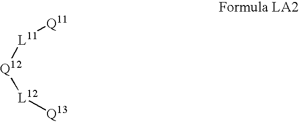

wherein Q¹¹ to Q¹³ and L¹¹ and L¹² are each a group having the same skeleton structure as that of the formula LA1, and may independently have a substituent.

Another aspect of the embodiment is that the metal complex is a compound represented by the following formula LA3, and the linear compound is a compound represented by the following formula LA4:

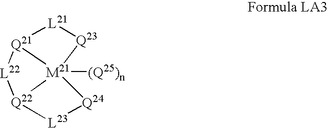

wherein M²¹ represents a metal ion; Q²¹ to Q²⁵ each independently represent a substitutent which coordinates with M²¹; L²¹ to L²³ each independently represent a single bond or a linking group; and n represents an integer of from 0 to 4,

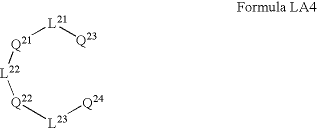

wherein Q²¹ to Q²⁴ and L²¹ to L²³ are each a group having the same skeleton structures as that of the formula LA3, and may independently have a substituent.

Further aspect of the embodiment is that the metal complex is a compound represented the following formula LA5, and the linear compound is a compound represented by the following formula LA6:

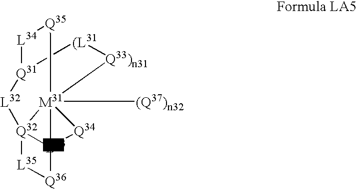

wherein M³¹ represents a metal ion; Q³¹ to Q³⁷ each independently represent a substituent which coordinates with M³¹; L³¹ to L³⁵ each independently represent a single bond or a linking group; and n31 and n32 each independently represent an integer of form 0 to 4,

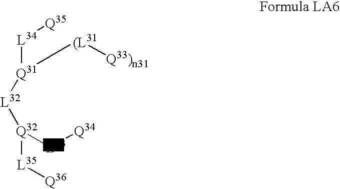

wherein Q³¹ to Q³⁶ and L³¹ to L³⁵ are each a group having the same skeleton structure as that of the formula LA5, and may independently have a substituent.

Still further aspect of the embodiment is that the metal complex is a compound represented by the following formula LA7, and the linear compound is a compound represented by the following formula LA8:

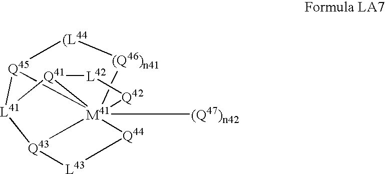

wherein M⁴¹ represents a metal ion; Q⁴¹ to Q⁴⁷ each independently represent a substituent which coordinates with M⁴¹; L⁴¹ to L⁴⁴ each independently represent a single bond or a linking group; and n41 and n42 each independently represent an integer of from 0 to 4,

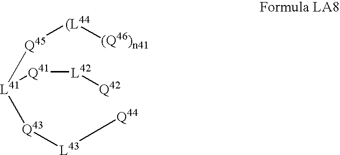

wherein Q⁴¹ to Q⁴⁶ and L⁴¹ to L⁴⁴ are each a group having the same skeleton structure as that of the formula LA7, and may independently have a substituent.

In the present invention, as shown in the above formulae (LA1) to (LA8), the multi-dentate metal complex and the metal-free compound include a substituent which is capable to coordinate with metal ion, such as Q¹¹ to Q¹⁴, Q²¹ to Q²⁵, Q³¹ to Q³⁷ and Q⁴¹ to Q⁴⁷, and a linking group, such as L¹¹ to L¹², L²¹ to L²³, L³¹ to L³⁵ and L⁴¹ to L⁴⁴.

The structural identity between the multi-dentate metal complex and the metal-free compound used in the present invention is defined as follows. The total number of a substituent capable of coordinating with metal ion and a linking group thereof contained in a multi-dentate metal complex molecule is estimated. And then the number same as that of the multi-dentate metal complex is estimated for a substituent and a linking group contained in a metal-free compound molecule. If the ratio of the number same as that of the multi-dentate metal complex among the substituent capable of coordinating with metal ion and the linking group contained in the metal-free compound molecule to the total number of the substituent and the linking group in the metal complex molecule results in 40% or more, it is defined in the present invention that they have the same skeleton structure. In the present invention, preferably 60% or more is the same skeleton structure, more preferably 80% or more is the same skeleton structure.

In the present invention, if the substituent capable of coordinating with metal ion or the linking group has the same skeleton structure, they are considered to be the same even if each group further has substituents or different substituents each other. Furthermore, even if the linking position is different from each other, they are considered to be mutually the same.

For example, in the case of the formulae (LA1) and (LA2), among Q¹¹ to Q¹³ and L¹¹ to L¹², preferably two or more parts are the same, more preferably three or more parts are the same, and still more preferably all parts are the same.

In the case of the formulae (LA3) and (LA4), among Q²¹ to Q²⁴ and L²¹ to L²³, preferably three or more parts are the same, more preferably five or more parts are the same, and still more preferably all parts are the same.

In the case of the formulae (LA5) and (LA6), among Q³¹ to Q³⁶ and L³¹ to L³⁵, preferably five or more parts are the same, more preferably eight or more parts are the same, and still more preferably all parts are the same.

In the case of the formulae (LA7) and (LA8), among Q⁴¹ to Q⁴⁶ and L⁴¹ to L⁴⁴, preferably four or more parts are the same, more preferably six or more parts are the same, and still more preferably all parts are the same.

Specific examples having the structural identity include following compounds, but it should be noted that the present invention is not limited thereto. For example, in the case of the metal complex Pt-1, the coordinated substituent includes two pyridine rings and two benzene rings, and therefore the total number of the coordinated substituent is four. On the other hand, the linking group thereof includes two single bonds which combine directly between the coordinated substituents and a dimethylmethylene group, and therefore, the number of linking group is three. Consequently, the total number of the coordinated substituent and the linking group is seven.

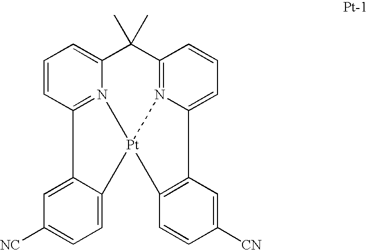

Similarly, among substituents capable of coordinating with metal ion and linking groups contained in the metal-free compounds L-1 to L-7 shown below, the number which is same as that of the metal complex Pt-1 is seven, and therefore, the identity ratio reaches to 100%.

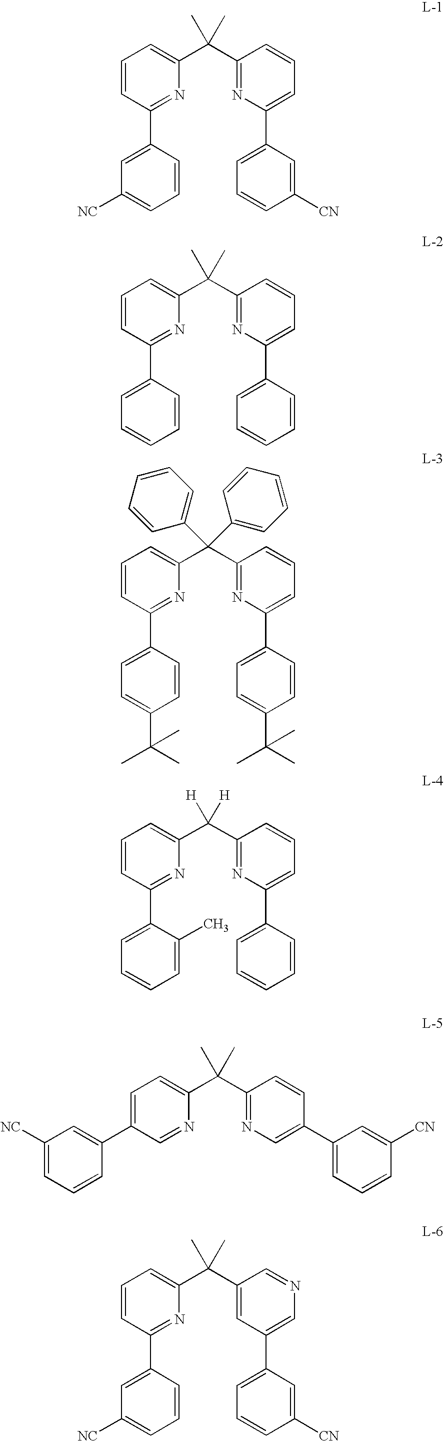

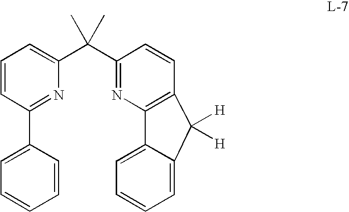

Among substituents capable of coordinating with metal ion and linking groups contained in the metal-free compounds L-8 to L-11 shown below, the number which is same as that of the metal complex Pt-1 is six, and therefore, the identity ratio amounts to 86%.

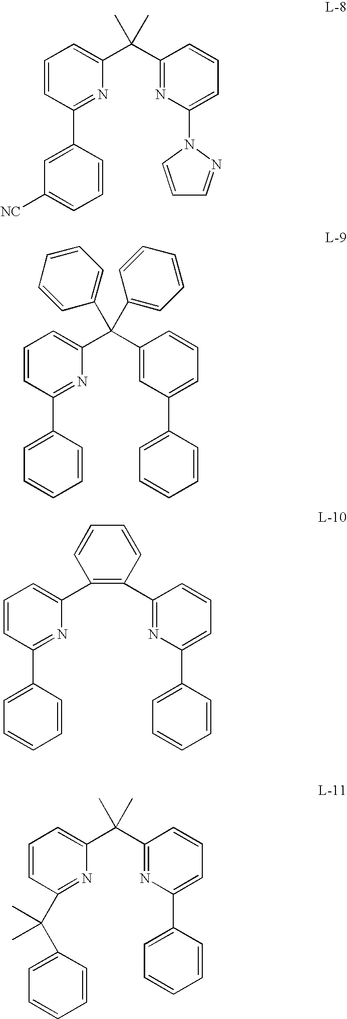

Among substituents capable of coordinating with metal ion and linking groups contained in the metal-free compounds L-12 to L-15 shown below, the number which is same as that of the metal complex Pt-1 is five, and therefore, the identity ratio amounts to 71%.

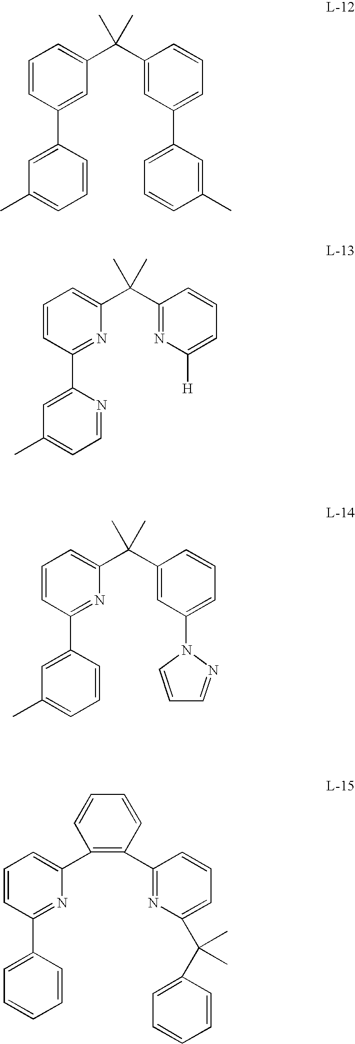

The metal-free compound mentioned above may have an effect in some extent independent of the ratio added, even if the compound is added in the light-emitting layer in combination with the light-emitting material. However, the ratio of the metal-free compound in the light-emitting layer is preferably in the range of from 1% to 50% by weight, more preferably from 2% to 40% by weight, and still more preferably from 5% to 30% by weight with respect to the host material.

When the content of the metal-free compound is less than the above range, it is unfavorable because the effect improving in the compatibility is decreased. When the content exceeds the above range, it is unfavorable because the charge transporting properties of the light-emitting layer become insufficient, and thereby a luminescence efficiency may be lowered.

According to the invention, the dispersibility of a polydentate metal complex used as a phosphorescent material is improved by a metal-free compound, and thus a uniformly stabilized layer is formed, and thereby, is provided a long-lifetime organic electroluminescent element having a high light emitting efficiency and an excellent driving durability.

2. Components of Organic Electroluminescent Element

In the following, the organic electroluminescent element of the present invention will be described in detail.

(Substrate)

According to the present invention, a substrate may be applied. The substrate to be applied is preferably one which does not scatter or attenuate light emitted from the organic compound layer. Specific examples of materials for the substrate include zirconia-stabilized yttrium (YSZ); inorganic materials such as glass; polyesters such as polyethylene terephthalate, polybutylene phthalate, and polyethylene naphthalate; and organic materials such as polystyrene, polycarbonate, polyethersulfon, polyarylate, polyimide, polycycloolefin, norbornene resin, poly(chlorotrifluoroethylene), and the like.

For instance, when glass is used as the substrate, non-alkali glass is preferably used with respect to the quality of material in order to decrease ions eluted from the glass. In the case of employing soda-lime glass, it is preferred to use glass on which a barrier coat such as silica has been applied. In the case of employing an organic material, it is preferred to use a material excellent in heat resistance, dimension stability, solvent resistance, electrical insulation, and workability.

There is no particular limitation as to the shape, the structure, the size or the like of the substrate, but it may be suitably selected according to the application, purposes and the like of the luminescent device. In general, a plate-like substrate is preferred as the shape of the substrate. A structure of the substrate may be a monolayer structure or a laminated structure. Furthermore, the substrate may be formed from a single member or two or more members.

Although the substrate may be in a transparent and colorless, or a transparent and colored condition, it is preferred that the substrate is transparent and colorless from the viewpoint that the substrate does not scatter or attenuate light emitted from the organic light-emitting layer.

A moisture permeation preventive layer (gas barrier layer) may be provided on the front surface or the back surface of the substrate.

For a material of the moisture permeation preventive layer (gas barrier layer), inorganic substances such as silicon nitride and silicon oxide may be preferably applied. The moisture permeation preventive layer (gas barrier layer) may be formed in accordance with, for example, a high-frequency sputtering method or the like.

In the case of applying a thermoplastic substrate, a hard-coat layer or an under-coat layer may be further provided as needed.

(Anode)

The anode may generally be any material as long as it has a function as an electrode for supplying positive holes to the organic compound layer, and there is no particular limitation as to the shape, the structure, the size or the like. However, it may be suitably selected from among well-known electrode materials according to the application and purpose of luminescent device. As mentioned above, the anode is usually provided as a transparent anode.

Materials for the anode may preferably include, for example, metals, alloys, metal oxides, electroconductive compounds, and mixtures thereof, and those having a work function of 4.0 eV or more are preferred. Specific examples of the anode materials include electroconductive metal oxides such as tin oxides doped with antimony, fluorine or the like (ATO and FTO), tin oxide, zinc oxide, indium oxide, indium tin oxide (ITO), and indium zinc oxide (IZO); metals such as gold, silver, chromium, and nickel; mixtures or laminates of these metals and the electroconductive metal oxides; inorganic electroconductive materials such as copper iodide and copper sulfide; organic electroconductive materials such as polyaniline, polythiophene, and polypyrrole; and laminates of these inorganic or organic electron-conductive materials with ITO. Among these, the electroconductive metal oxides are preferred, and particularly, ITO is preferable in view of productivity, high electroconductivity, transparency and the like.

The anode may be formed on the substrate in accordance with a method which is appropriately selected from among wet methods such as printing methods, coating methods and the like; physical methods such as vacuum deposition methods, sputtering methods, ion plating methods and the like; and chemical methods such as CVD and plasma CVD methods and the like, in consideration of the suitability to a material constituting the anode. For instance, when ITO is selected as a material for the anode, the anode may be formed in accordance with a DC or high-frequency sputtering method, a vacuum deposition method, an ion plating method or the like.

In the organic electroluminescent element of the present invention, a position at which the anode is to be formed is not particularly limited, but it may be suitably selected according to the application and purpose of the luminescent device. The anode may be formed on either the whole surface or a part of the surface on either side of the substrate.

For patterning to form the anode, a chemical etching method such as photolithography, a physical etching method such as etching by laser, a method of vacuum deposition or sputtering through superposing masks, or a lift-off method or a printing method may be applied.

A thickness of the anode may be suitably selected according to the material constituting the anode and is therefore not definitely decided, but it is usually in the range of around 10 nm to 50 μm, and preferably 50 nm to 20 μm.

A value of resistance of the anode is preferably 10³Ω/□ or less, and 10²Ω/□ or less is more preferable. In the case where the anode is transparent, it may be either transparent and colorless, or transparent and colored. For extracting luminescence from the transparent anode side, it is preferred that a light transmittance of the anode is 60% or higher, and more preferably 70% or higher.

Concerning transparent anodes, there is a detailed description in “TOUMEI DENNKYOKU-MAKU NO SHINTENKAI (Novel Developments in Transparent Electrode Films)” edited by Yutaka Sawada, published by C.M.C. in 1999, the contents of which are incorporated by reference herein. In the case where a plastic substrate having a low heat resistance is applied, it is preferred that ITO or IZO is used to obtain a transparent anode prepared by forming the film at a low temperature of 150° C. or lower.

(Cathode)

The cathode may generally be any material as long as it has a function as an electrode for injecting electrons to the organic compound layer, and there is no particular limitation as to the shape, the structure, the size or the like. However it may be suitably selected from among well-known electrode materials according to the application and purpose of the luminescent device.

Materials constituting the cathode may include, for example, metals, alloys, metal oxides, electroconductive compounds. Specific examples thereof include alkali metals (e.g., Li, Na, K, Cs or the like), alkaline earth metals (e.g., Mg, Ca or the like), gold, silver, lead, aluminum, sodium-potassium alloys, lithium-aluminum alloys, magnesium-silver alloys, rare earth metals such as indium, and ytterbium, and the like. They may be used alone, but it is preferred that two or more of them are used in combination from the viewpoint of satisfying both stability and electron injectability.

Among these, as the materials for constituting the cathode, alkaline metals or alkaline earth metals are preferred in view of electron injectability, and materials containing aluminum as a major component are preferred in view of excellent preservation stability.

The term “material containing aluminum as a major component” refers to a material constituted by aluminum alone; alloys comprising aluminum and 0.01% by weight to 10% by weight of an alkaline metal or an alkaline earth metal; or the mixtures thereof (e.g., lithium-aluminum alloys, magnesium-aluminum alloys and the like).

Regarding materials for the cathode, they are described in detail in JP-A Nos. 2-15595 and 5-121172, of which are incorporated by reference herein.

A method for forming the cathode is not particularly limited, but it may be formed in accordance with a well-known method.

For instance, the cathode may be formed in accordance with a method which is appropriately selected from among wet methods such as printing methods, coating methods and the like; physical methods such as vacuum deposition methods, sputtering methods, ion plating methods and the like; and chemical methods such as CVD and plasma CVD methods and the like, in consideration of the suitability to a material constituting the cathode. For example, when a metal (or metals) is (are) selected as a material (or materials) for the cathode, one or two or more of them may be applied at the same time or sequentially in accordance with a sputtering method or the like.

For patterning to form the cathode, a chemical etching method such as photolithography, a physical etching method such as etching by laser, a method of vacuum deposition or sputtering through superposing masks, or a lift-off method or a printing method may be applied.

In the present invention, a position at which the cathode is to be formed is not particularly limited, and it may be formed on either the whole or a part of the organic compound layer.

Furthermore, a dielectric material layer made of fluorides, oxides or the like of an alkaline metal or an alkaline earth metal may be inserted in between the cathode and the organic compound layer with a thickness of 0.1 nm to 5 nm. The dielectric layer may be considered to be a kind of electron injection layer. The dielectric material layer may be formed in accordance with, for example, a vacuum deposition method, a sputtering method, an ion-plating method or the like.

A thickness of the cathode may be suitably selected according to materials for constituting the cathode and is therefore not definitely decided, but it is usually in the range of around 10 nm to 5 μm, and preferably 50 nm to 1 μm.

Moreover, the cathode may be transparent or opaque. The transparent cathode may be formed by preparing a material for the cathode with a small thickness of 1 nm to 10 nm, and further laminating a transparent electroconductive material such as ITO or IZO thereon.

(Organic Compound Layer)

The organic electroluminescent element of the present invention has at least one organic compound layer including a light emitting layer. Examples of the organic compound layers other than the light emitting layer include, as mentioned above, respective layers of a hole transport layer, an electron transport layer, a charge blocking layer, an hole injection layer, an electron injection layer and the like.

The respective layers that constitute organic compound layers in the present invention can be preferably formed by any method of dry layering methods such as a vapor deposition method and a sputtering method, a wet coating method, a transferring method, a printing method, a ink jet method, or the like

(Light-Emitting Layer)

The light-emitting layer is a layer having a function for receiving positive holes from the anode, the positive hole injection layer, the positive hole transport layer or the positive hole transporting buffer layer, and receiving electrons from the cathode, the electron injection layer, the electron-transport layer, or the electron transporting buffer layer, and for providing a field for recombination of the positive holes with the electrons to emit a light.

The light-emitting layer according to the invention includes at least a metal complex having a tri-dentate or higher multi-dentate ligand as a light emitting material, and a metal-free compound capable of giving a three or higher coordination with a central metal of the metal complex.

Preferably, the coordination number of the metal-free compound is same as the coordination number of the metal complex. Preferably, the chemical structure of the metal-free compound is the same as the chemical structure in which metal is removed from the metal complex. Preferably, the polydentate ligand included in the metal complex and the metal-free compound are a linear compound.

Even if any ratio of the metal complex having a tri-dentate or higher multi-dentate ligand with respect to the entire light-emitting layer is selected to be used, the selected ratio is in the range of the invention, but the ratio is preferably in the range of 0.1% by weight to 50% by weight, and more preferably in the range of 3% by weight to 30% by weight, with respect to that of the entire light-emitting layer. Even if any ratio of the metal-free compound capable of giving a three or higher coordination with a metal which is the same to a central metal of the metal complex with respect to the entire light-emitting layer is selected to be used, the selected ratio is in the range of the invention. A light-emitting layer may be composed of two compounds, that is, a metal-free compound and a metal compound as a light emitting material, and may be composed by a combination of the two compounds and other host materials.

The thickness of the light-emitting layer is not particularly limited as long as it can provide an effect of the invention, but the thickness of the light-emitting layer is preferably in the range of 10 nm to 70 nm, and more preferably in the range of 20 nm to 60 nm.

<Metal Complex Including Tri-Dentate or Higher Multi-Dentate Ligand>

The light emitting material used in the invention may be a fluorescence material or a phosphorescence material, but preferably is a phosphorescence material which includes at least a metal complex having a tri-dentate or higher multi-dentate ligand as a phosphorescent material.

Specific examples of the metal complex having a tri-dentate or higher multi-dentate ligand include the following compounds, but it should be noted that the present invention is not limited thereto.

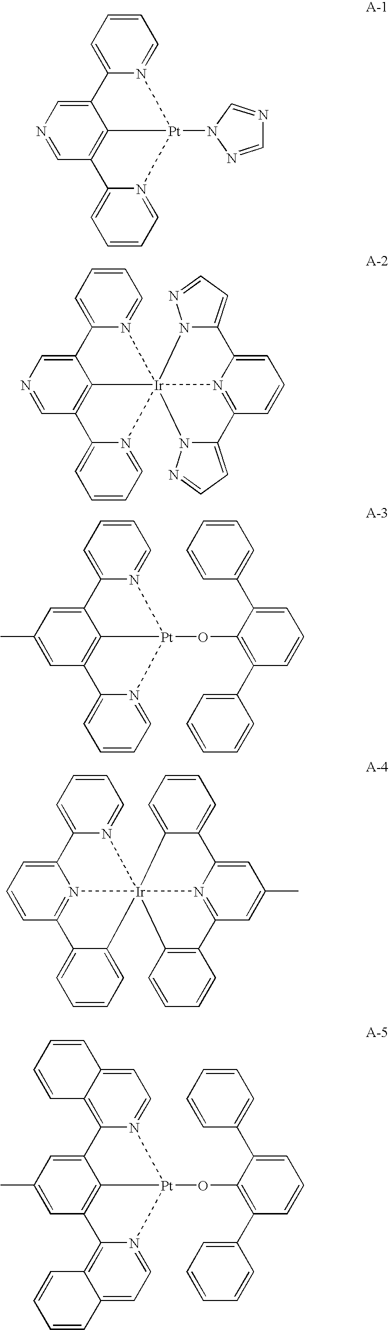

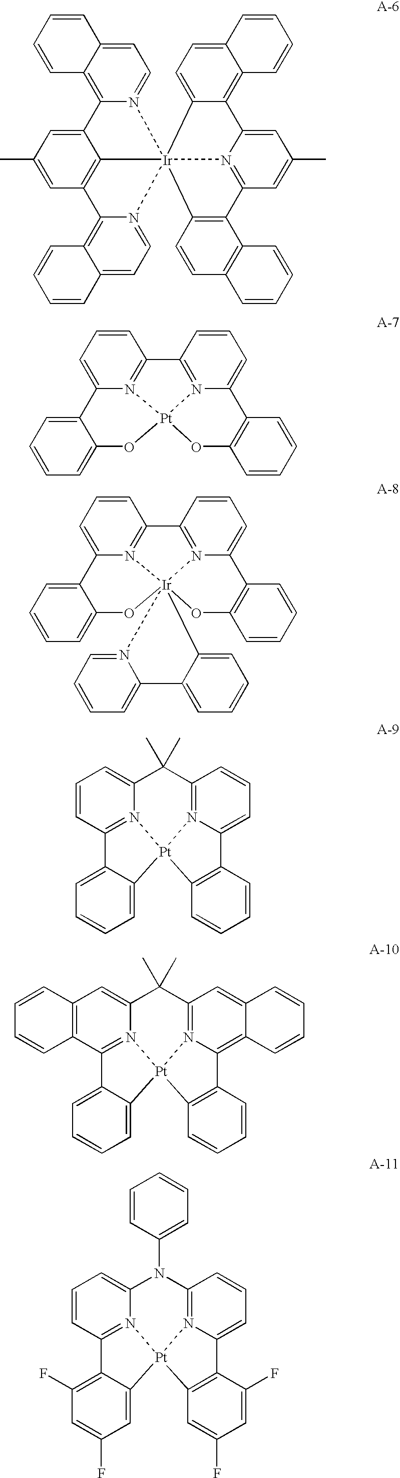

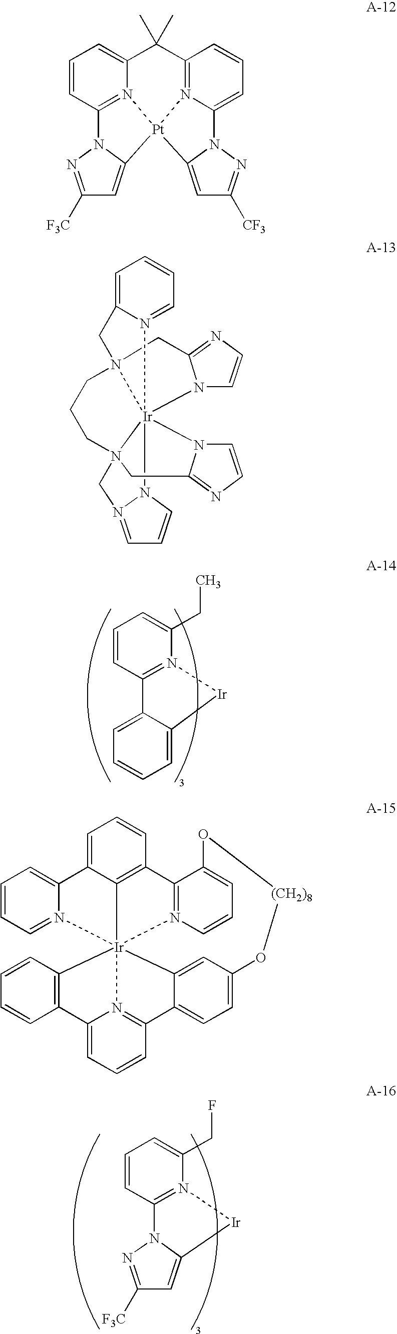

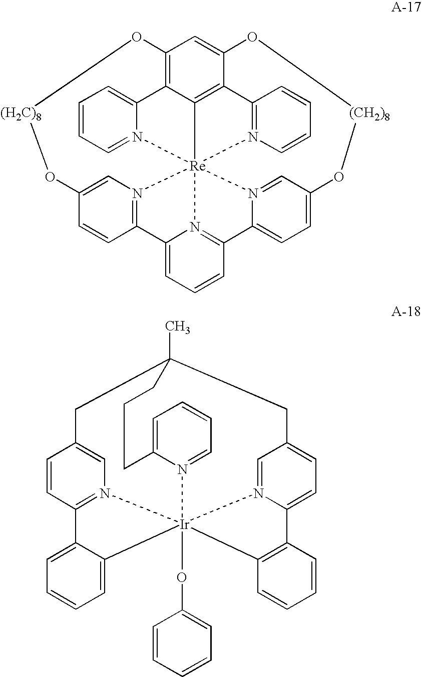

<Metal-Free Compound Capable of Giving Three or Higher Coordination with Central Metal of Metal Complex>

The light-emitting layer used in the invention includes a metal-free compound capable of giving a three or higher coordination with a metal which is the same to a central metal of a metal complex having a tri-dentate or higher multi-dentate ligand as a light emitting material. A compound having a structure similar to the ligand of the light emitting material included in the light-emitting layer is effectively used as a metal-free compound. In addition, a compound having a chemical structure that the metal is removed from a light emitting material as a partial structure is preferably used as a metal-free compound. In this case, a moiety where the metal is to be bonded is preferably hydrogenated or substituted by other substituent, instead of metals. For a metal-free compound, it is necessary to have a structure similar to the structure of a ligand of a light emitting material. However, the structure of a metal-free compound may not be entirely the same as the structure of a ligand, and the same effect can be expected even if a metal-free compound may include any other substituents.

Specific examples of the metal-free compound capable of giving a three or higher coordination with a central metal of a metal complex include the following compounds, but it should be noted that the present invention is not limited thereto. 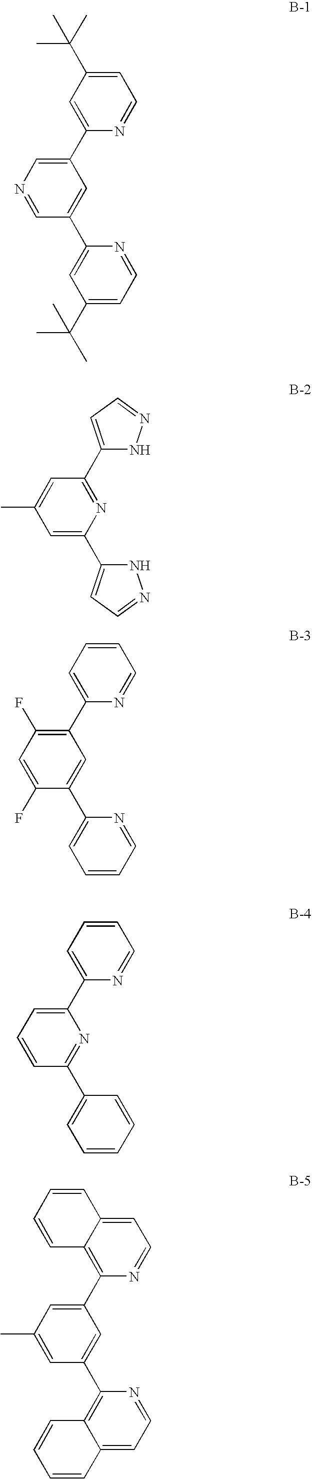 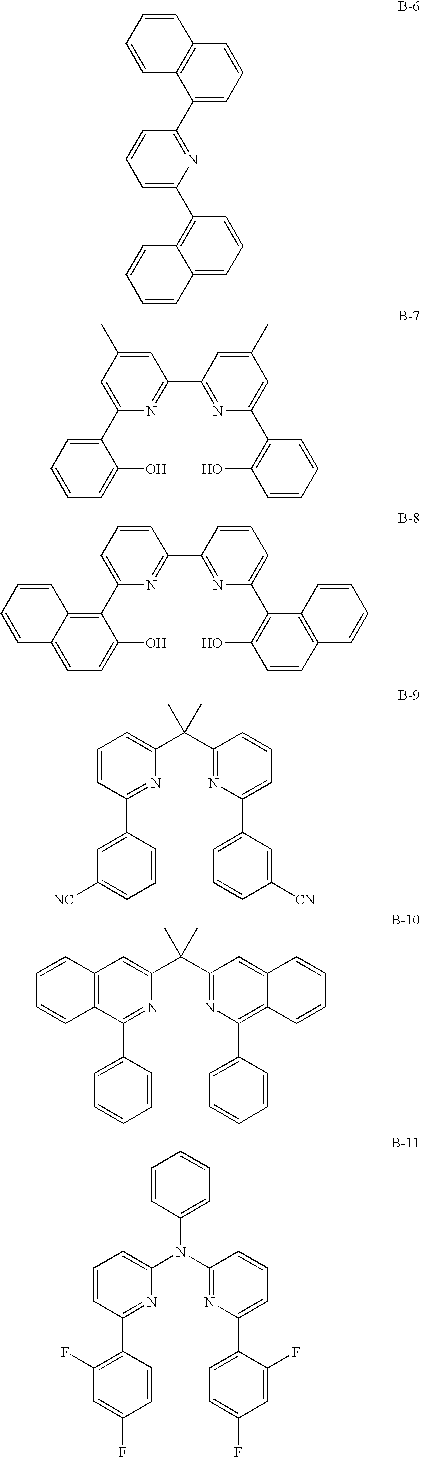 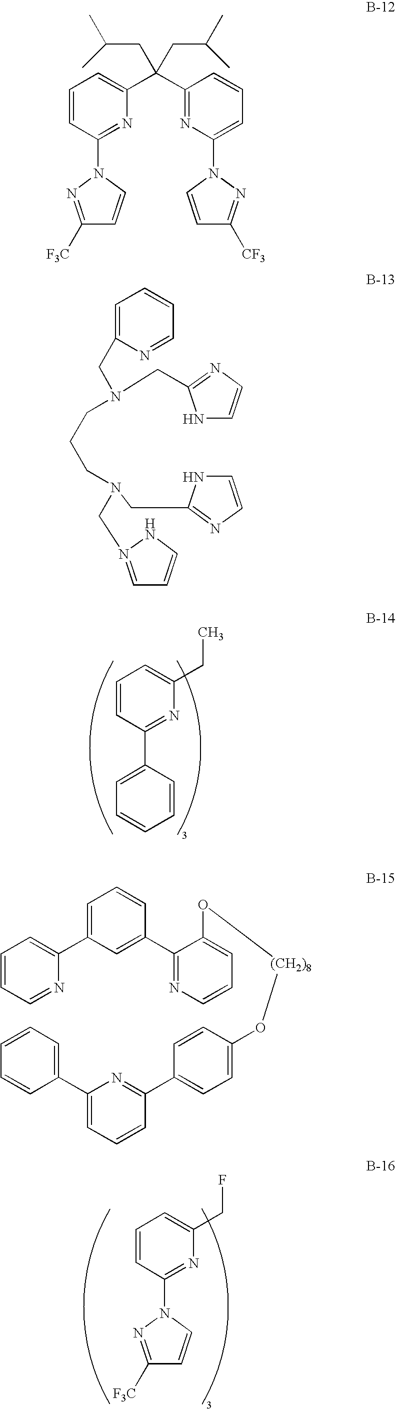 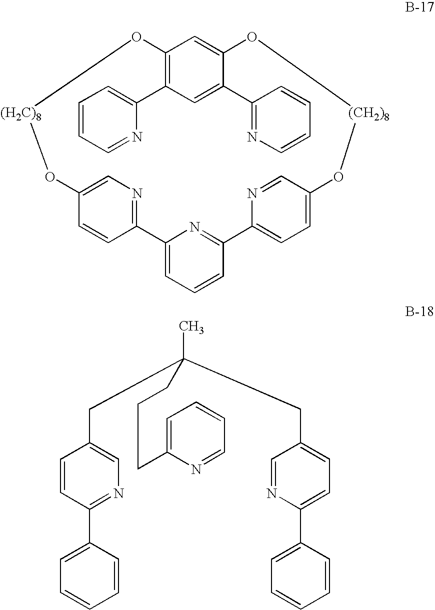
(Host Material)

As the host materials to be used according to the present invention, positive hole transporting host materials excellent in positive hole transporting property (referred to as a “positive hole transporting host” in some cases) and electron transporting host compounds excellent in electron transporting property (referred to as an “electron transporting host” in some cases) may be used.

<<Positive Hole Transporting Host>>

Specific examples of such positive hole transporting hosts as mentioned above include pyrrole, carbazole, azacarbazole, indole, azaindole, pyrazole, imidazole, polyarylalkane, pyrazoline, pyrazolone, phenylenediamine, arylamine, amino-substituted chalcone, styrylanthracene, fluorenone, hydrazone, stilbene, silazane, aromatic tertiary amine compounds, styrylamine compounds, aromatic dimethylidine compounds, porphyrin compounds, polysilane compounds, poly(N-vinylcarbazole), aniline copolymers, electroconductive high-molecular oligomers such as thiophene oligomers, polythiophenes and the like, organic silanes, carbon films, derivatives thereof, and the like.

Among these, carbazole derivatives, aromatic tertiary amine compounds, and thiophene derivatives are preferable, more preferably a compound having a carbazole group in a molecular, and particularly preferable a compound having at-butyl-carbazole group in a molecular.

As specific examples of the positive hole transporting hosts described above, the following compounds may be listed, but the present invention is not limited thereto.

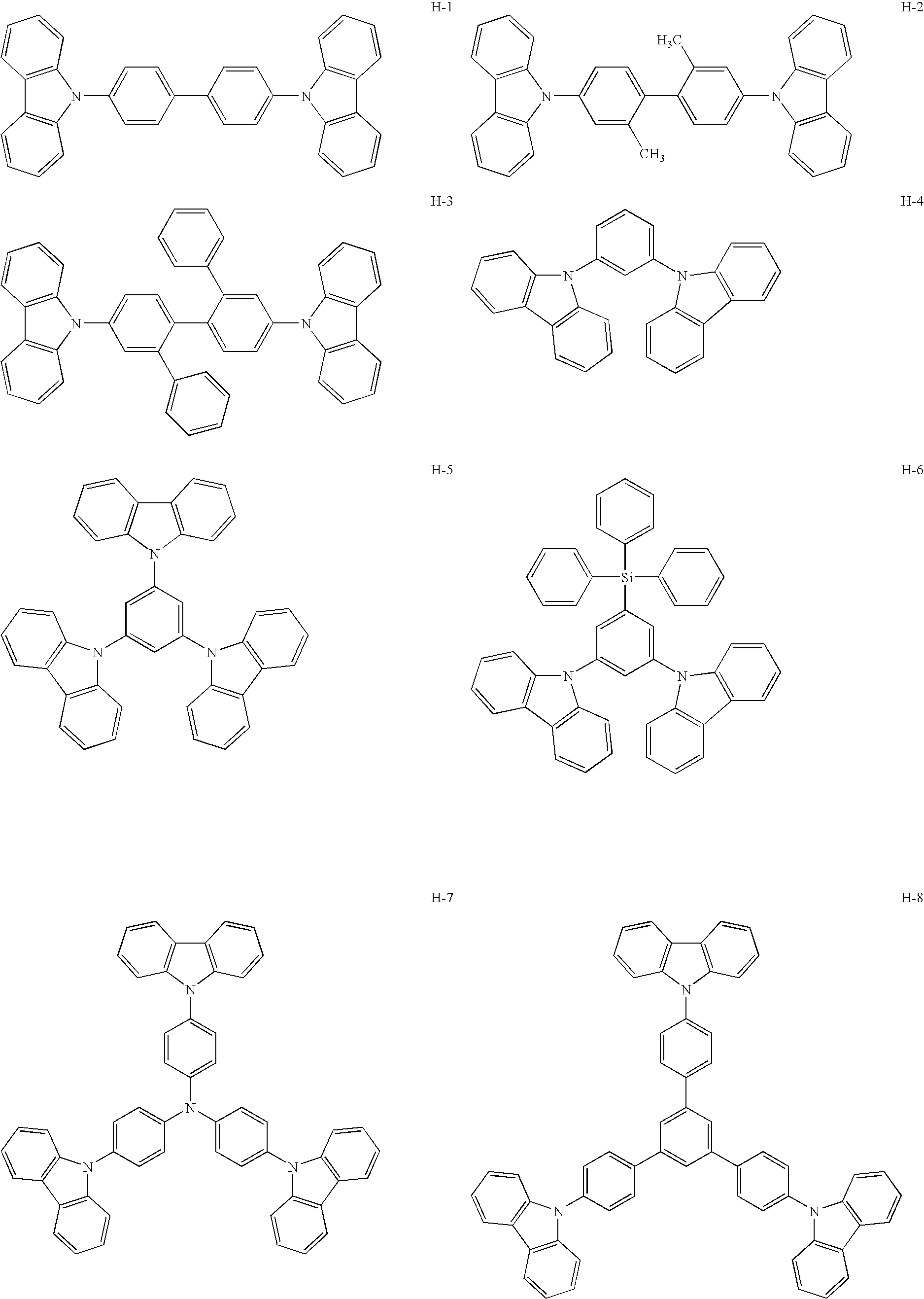

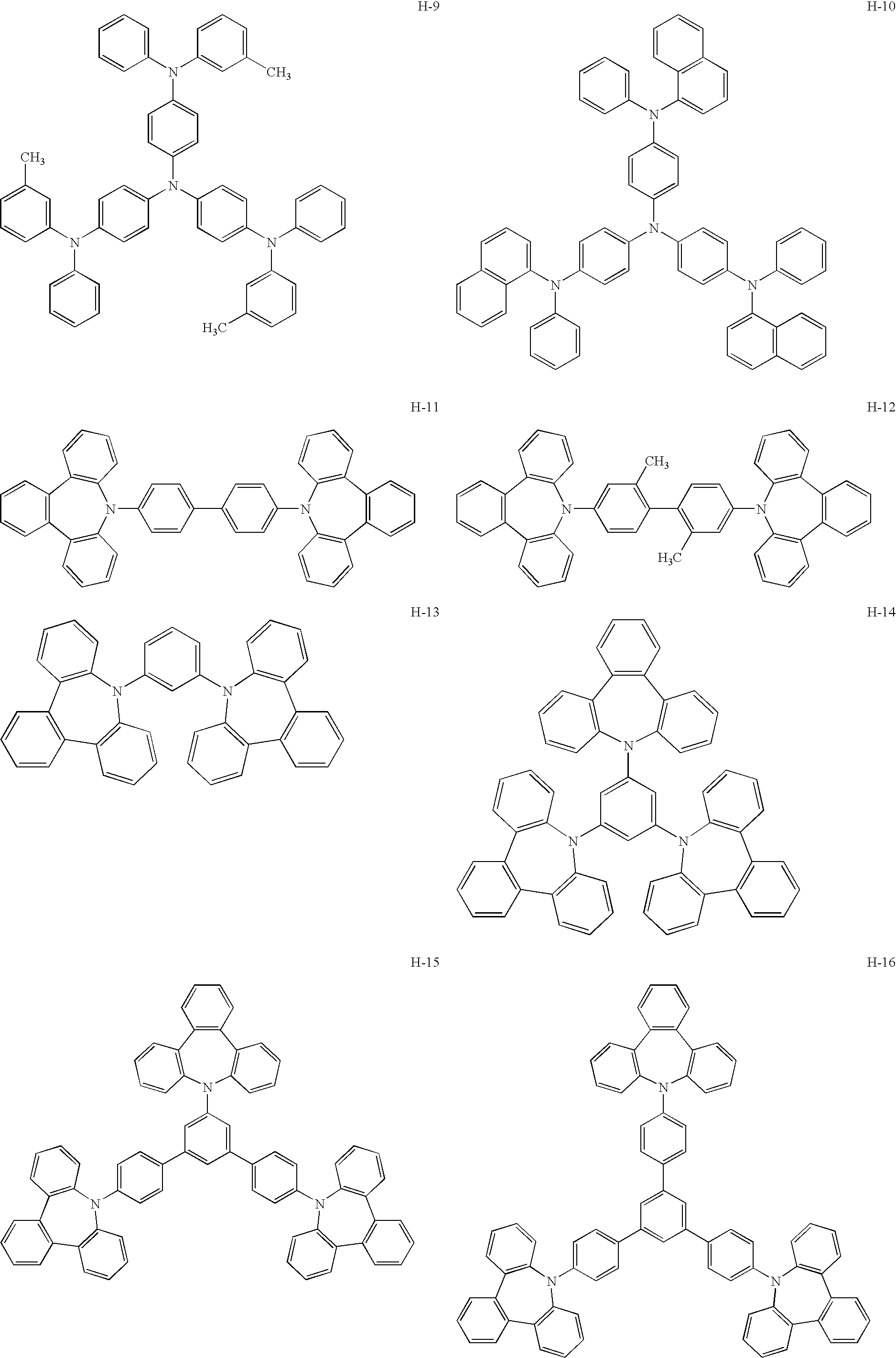

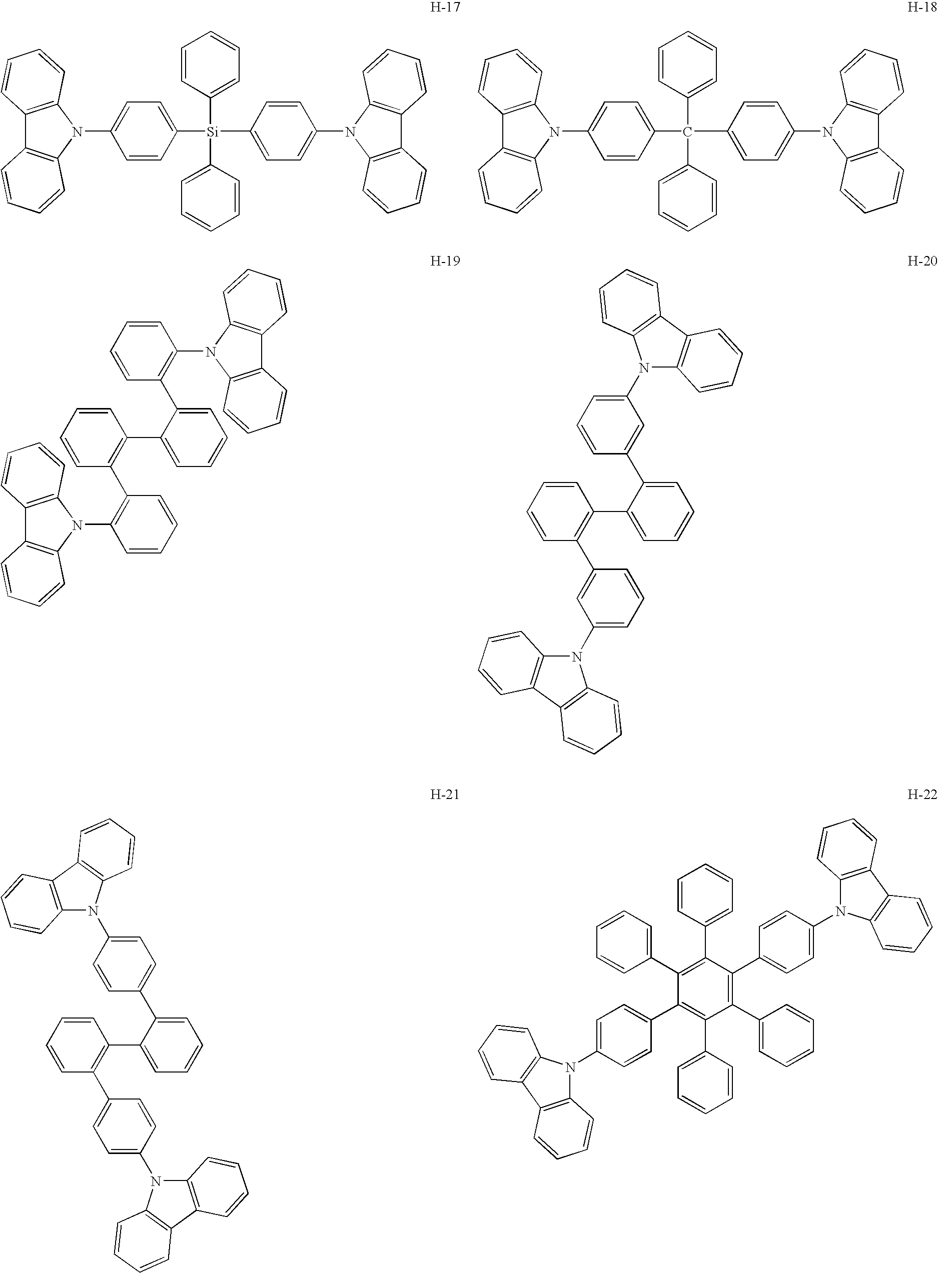

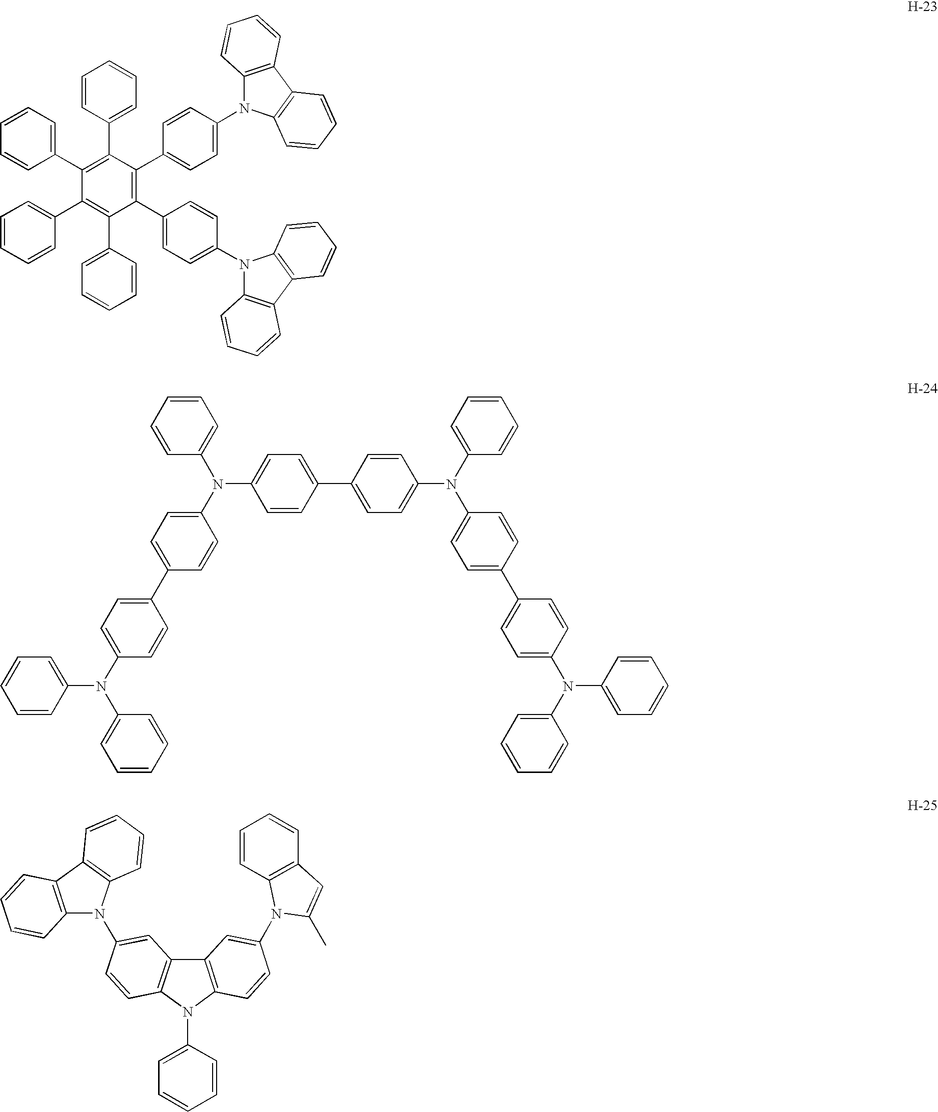

<<Electron Transporting Host>>

As the electron transporting host used according to the present invention, it is preferred that an electron affinity Ea of the host is 2.5 eV to 3.5 eV, more preferably 2.6 eV to 3.4 eV, and further preferably 2.8 eV to 3.3 eV in view of improvements in durability and decrease in driving voltage. Furthermore, it is preferred that an ionization potential Ip of the host is 5.7 eV to 7.5 eV, more preferably 5.8 eV to 7.0 eV, and further preferably 5.9 eV to 6.5 eV in view of improvements in durability and decrease in driving voltage.

Specific examples of such electron transporting hosts as mentioned above include pyridine, pyrimidine, triazine, imidazole, pyrazole, triazole, oxazole, oxadiazole, fluorenone, anthraquinonedimethane, anthrone, diphenylquinone, thiopyrandioxide, carbodiimide, fluorenylidenemethane, distyrylpyradine, fluorine-substituted aromatic compounds, heterocyclic tetracarboxylic anhydrides such as naphthaleneperylene and the like, phthalocyanine, derivatives thereof (which may form a condensed ring with another ring), and a variety of metal complexes represented by metal complexes of 8-quinolynol derivatives, metal phthalocyanines, and metal complexes having benzoxazole or benzothiazole as the ligand.

Preferable electron transporting hosts are metal complexes, azole derivatives (benzimidazole derivatives, imidazopyridine derivatives and the like), and azine derivatives (pyridine derivatives, pyrimidine derivatives, triazine derivatives and the like). Among these, metal complexes are preferred according to the present invention in view of durability. As the metal complex compound, a metal complex containing a ligand having at least one nitrogen atom, oxygen atom, or sulfur atom to be coordinated with the metal is more preferable.

Although a metal ion in the metal complex is not particularly limited, a beryllium ion, a magnesium ion, an aluminum ion, a gallium ion, a zinc ion, an indium ion, a tin ion, a platinum ion, or a palladium ion is preferred; more preferable is a beryllium ion, an aluminum ion, a gallium ion, a zinc ion, a platinum ion, or a palladium ion; and further preferable is an aluminum ion, a zinc ion, or a palladium ion.

Although there are a variety of well-known ligands to be contained in the above-described metal complexes, examples thereof include ligands described in “Photochemistry and Photophysics of Coordination Compounds” authored by H. Yersin, published by Springer-Verlag Company in 1987; “YUHKI KINZOKU KAGAKU—KISO TO OUYOU—(Metalorganic Chemistry—Fundamental and Application—)” authored by Akio Yamamoto, published by Shokabo Publishing Co., Ltd. in 1982, and the like.

The ligands are preferably nitrogen-containing heterocyclic ligands (having preferably 1 to 30 carbon atoms, more preferably 2 to 20 carbon atoms, and particularly preferably 3 to 15 carbon atoms); and they may be a unidentate ligand or a bi- or higher-dentate ligand. Preferable are bi- to hexa-dentate ligands, and mixed ligands of bi- to hexa-dentate ligands with a unidentate ligand are also preferable.

Examples of the ligands include azine ligands (e.g. pyridine ligands, bipyridyl ligands, terpyridine ligands and the like); hydroxyphenylazole ligands (e.g. hydroxyphenylbenzimidazole ligands, hydroxyphenylbenzoxazole ligands, hydroxyphenylimidazole ligands, hydroxyphenylimidazopyridine ligands and the like); alkoxy ligands (those having preferably 1 to 30 carbon atoms, more preferably 1 to 20 carbon atoms, and particularly preferably 1 to 10 carbon atoms, examples of which include methoxy, ethoxy, butoxy, 2-ethylhexyloxy and the like); aryloxy ligands (those having preferably 6 to 30 carbon atoms, more preferably 6 to 20 carbon atoms, and particularly preferably 6 to 12 carbon atoms, examples of which include phenyloxy, 1-naphthyloxy, 2-naphthyloxy, 2,4,6-trimethylphenyloxy, 4-biphenyloxy and the like); heteroaryloxy ligands (those having preferably 1 to 30 carbon atoms, more preferably 1 to 20 carbon atoms, and particularly preferably 1 to 12 carbon atoms, examples of which include pyridyloxy, pyrazyloxy, pyrimidyloxy, quinolyloxy and the like); alkylthio ligands (those having preferably 1 to 30 carbon atoms, more preferably 1 to 20 carbon atoms, and particularly preferably 1 to 12 carbon atoms, examples of which include methylthio, ethylthio and the like); arylthio ligands (those having preferably 6 to 30 carbon atoms, more preferably 6 to 20 carbon atoms, and particularly preferably 6 to 12 carbon atoms, examples of which include phenylthio and the like); heteroarylthio ligands (those having preferably 1 to 30 carbon atoms, more preferably 1 to 20 carbon atoms, and particularly preferably 1 to 12 carbon atoms, examples of which include pyridylthio, 2-benzimidazolylthio, benzooxazolylthio, 2-benzothiazolylthio and the like); siloxy ligands (those having preferably 1 to 30 carbon atoms, more preferably 3 to 25 carbon atoms, and particularly preferably 6 to 20 carbon atoms, examples of which include a triphenylsiloxy group, a triethoxysiloxy group, a triisopropylsiloxy group and the like); aromatic hydrocarbon anion ligands (those having preferably 6 to 30 carbon atoms, more preferably 6 to 25 carbon atoms, and particularly preferably 6 to 20 carbon atoms, examples of which include a phenyl anion, a naphthyl anion, an anthranyl anion and the like anion); aromatic heterocyclic anion ligands (those having preferably 1 to 30 carbon atoms, more preferably 2 to 25 carbon atoms, and particularly preferably 2 to 20 carbon atoms, examples of which include a pyrrole anion, a pyrazole anion, a triazole anion, an oxazole anion, a benzoxazole anion, a thiazole anion, a benzothiazole anion, a thiophene anion, a benzothiophene anion and the like); indolenine anion ligands and the like. Among these, nitrogen-containing heterocyclic ligands, aryloxy ligands, heteroaryloxy groups, aromatic hydrocarbon anion ligands, aromatic heterocyclic anion ligands or siloxy ligands are preferable, and nitrogen-containing heterocyclic ligands, aryloxy ligands, siloxy ligands, aromatic hydrocarbon anion ligands, or aromatic heterocyclic anion ligands are more preferable.

Examples of the metal complex electron transporting hosts include compounds described, for example, in Japanese Patent Application Laid-Open Nos. 2002-235076, 2004-214179, 2004-221062, 2004-221065, 2004-221068, 2004-327313 and the like.

Specific examples of these electron transporting hosts include the following materials, but it should be noted that the present invention is not limited thereto.

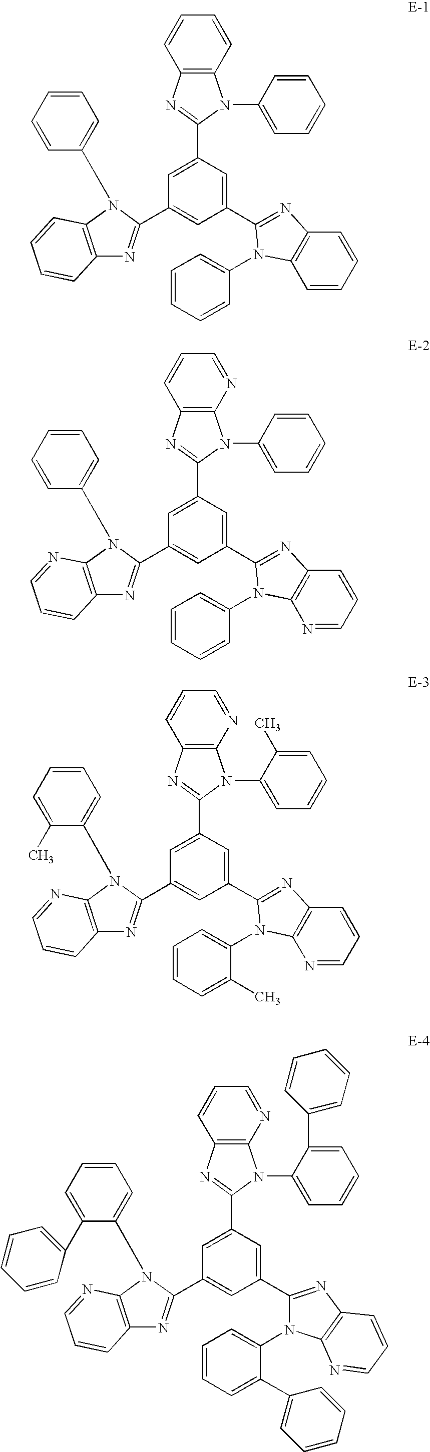

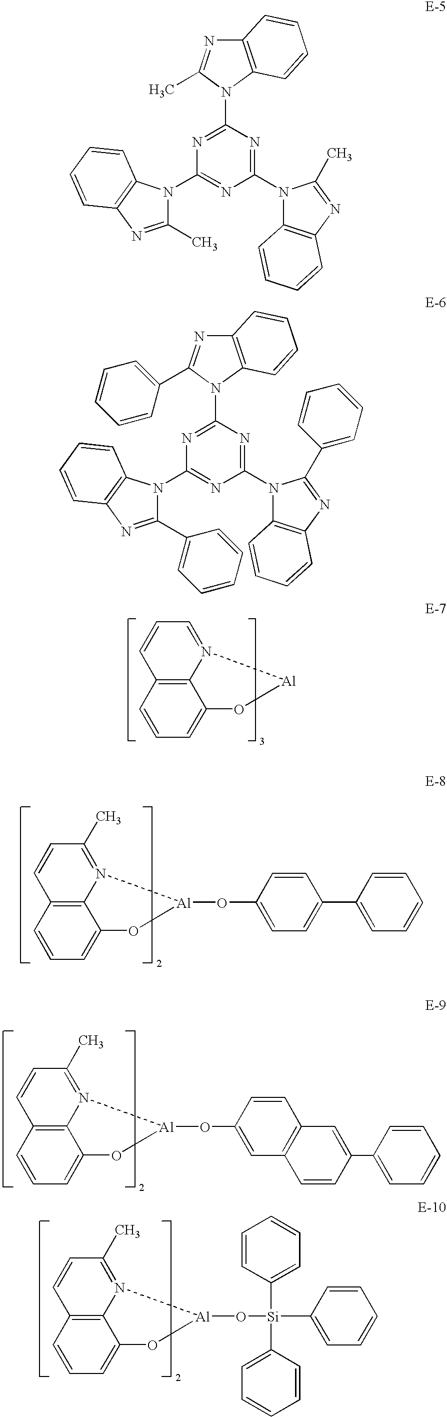

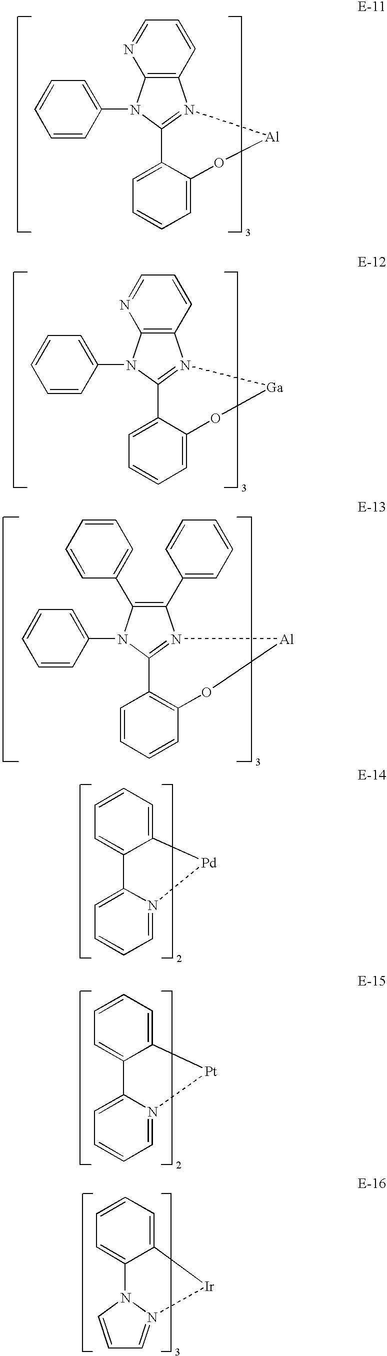

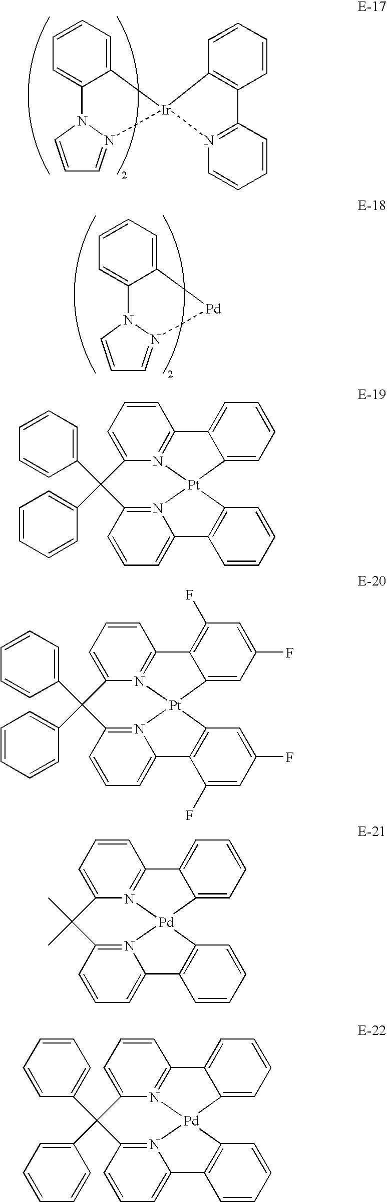

As the electron transportation hosts, E-1 to E-6, E-8, E-9, E-10, E-21, or E-22 is preferred, E-3, E-4, E-6, E-8, E-9, E-10, E-21, or E-22 is more preferred, and E-3, E-4, E-21, or E-22 is further preferred.

Although a content of the host compounds according to the present invention is not particularly limited, it is preferably 15% by weight to 95% by weight with respect to the total mass of the compounds forming the light-emitting layer in view of luminescence efficiency and driving voltage.

(Hole Injection Layer and Hole Transport Layer)

The hole injection layer and hole transport layer correspond to layers functioning to receive holes from an anode or from an anode side and to transport the holes to a cathode side.

As a material for the positive hole injection layer and the positive hole transport layer, it is preferred to contain specifically pyrrole derivatives, carbazole derivatives, pyrazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted calcon derivatives, styrylanthracene derivatives, fluorenone derivatives, hydrazone derivatives, stilbene derivatives, silazane derivatives, aromatic tertiary amine compounds, styrylamine derivatives, aromatic dimethylidine compounds, porphyrin compounds, organosilane derivatives, carbon or the like.

The positive hole injection layer and the positive hole transport layer in the present invention preferably contain an electron-accepting dopant. Either of an inorganic compound or an organic compound may be used as long as the compound has electron accepting property and a function for oxidizing an organic compound.

Specifically, inorganic compounds such as halides compounds, for example, ferric chloride, aluminum chloride, gallium chloride, indium chloride, antimony pentachloride and the like, and metal oxides such as vanadium pentaoxide, molybdenum trioxide and the like are preferably used as the inorganic compounds.

In case of the organic compounds, compounds having substituents such as a nitro group, a halogen, a cyano group, a trifluoromethyl group and the like; quinone compounds; acid anhydride compounds; fullerenes; and the like may be preferably applied.

Another specific examples thereof include compounds described in patent documents such as Japanese Patent Application Laid-Open (JP-A) Nos. 6-212153, 11-111463, 11-251067. 2000-196140, 2000-286054, 2000-315580, 2001-102175, 2001-160493, 2002-252085, 2002-56985, 2003-157981, 2003-217862, 2003-229278, 2004-342614, 2005-72012, 2005-166637, 2005-209643 and the like.

Among these, hexacyanobutadiene, hexacyanobenzene, tetracyanoethylene, tetracyanoquinodimethane, tetrafluorotetracyanoquinodimethane, p-fluoranil, p-chloranil, p-bromanil, p-benzoquinone, 2,6-dichlorobenzoquinone, 2,5-dichlorobenzoquinone, 1,2,4,5-tetracyanobenzene, 1,4-dicyanotetrafluorobenzene, 2,3-dichloro-5,6-dicyanobenzoquinone, p-dinitrobenzene, m-dinitrobenzene, o-dinitrobenzene, 1,4-naphthoquinone, 2,3-dichloronaphthoquinone, 1,3-dinitronaphthalene, 1,5-dinitronaphthalene, 9,10-anthraquinone, 1,3,6,8-tetranitrocarbazole, 2,4,7-trinitro-9-fluorenone, 2,3,5,6-tetracyanopyridine, or fullerene C60 is preferable. Hexacyanobutadiene, hexacyanobenzene, tetracyanoethylene, tetracyanoquinodimethane, tetrafluorotetracyanoquinodimethane, p-fluoranil, p-chloranil, p-bromanil, 2,6-dichlorobenzoquinone, 2,5-dichlorobenzoquinone, 2,3-dichloronaphthoquinone, 1,2,4,5-tetracyanobenzene, 2,3-dichloro-5,6-dicyanobenzoquinone, or 2,3,5,6-tetracyanopyridine is particularly preferred, and tetrafluorotetracyanoquinodimethane is most particularly preferred.

These electron-accepting dopants may be used alone or in a combination of two or more of them.

Although an applied amount of these electron-accepting dopants depends on the type of material, 0.01% by weight to 50% by weight is preferred with respect to a hole transport layer material, 0.05% by weight to 20% by weight is more preferable, and 0.1% by weight to 10% by weight is particularly preferred.

The thickness of the positive hole injection layer and the positive hole transport layer is preferably 500 nm or less in view of decrease in driving voltage.

The thickness of the positive hole transport layer is preferably 1 nm to 500 nm, more preferably 5 nm to 50 nm, and more preferably 10 nm to 40 nm. The thickness of the positive hole injection layer is preferably 0.1 nm to 500 nm, more preferably 0.5 nm to 300 nm, and more preferably 1 nm to 200 nm.

The hole injection layer and the hole transport layer may be composed of a mono-layered structure comprising one or two or more of the above-mentioned materials, or a multilayer structure composed of plural layers of a homogeneous composition or heterogeneous compositions.

(Electron Injection Layer and Electron-Transport Layer)

The electron injection layer and the electron-transport layer are layers having any of functions for injecting electrons from the cathode, transporting electrons, and becoming a barrier to positive holes which could be injected from the anode.

Specifically, these layers are preferably those containing a pyridine derivative, a quinoline derivative, a pyrimidine derivative, a pyrazine derivative, a phthalazine derivative, a phenanthroline derivative, a triazine derivative, a triazole derivative, an oxazole derivative, an oxadiazole derivative, an imidazole derivative, a fluorenone derivative, an anthraquinodimethane derivative, an anthrone derivative, a diphenylquinone derivative, a thiopyran dioxide derivative, a carbodiimide derivative, a fluorenylidenemethane derivative, a distyrylpyrazine derivative, a tetracarboxylic anhydride of an aromatic compound such as naphthalene or perylene, a phthalocyanine derivative, various metal complexes as typically represented by a metal complex of a 8-quinolinol derivative or metallophthalocyanine, a metal complex containing benzoxazole or benzothiazole as a ligand, or an organic silane derivative typically represented by silole.

The electron injection layer and the electron-transport layer in the present invention may include an electron-donating dopant. As a material applied for the electron-donating dopant with respect to the electron injection layer or the electron-transport layer, any material may be used as long as it has an electron-donating property and a property for reducing an organic compound, and alkaline metals such as Li, alkaline earth metals such as Mg, transition metals including rare-earth metals, reductive organic compounds and the like are preferably used. Particularly, metals having a work function of 4.2 V or less are preferably applied, and specific examples thereof include Li, Na, K, Be, Mg, Ca, Sr, Ba, Y, Cs, La, Sm, Gd, and Yb. The examples of reductive organic compounds are, for example, a nitrogen containing compound, a sulfur containing compound, a phosphor containing compound and the like.

In addition, there may be utilized materials described in Japanese Patent Application Laid-Open (JP-A) Nos. 6-212153, 2000-196140, 2003-68468, 2003-229278 and 2004-342614.

These electron-donating dopants may be used alone or in a combination of two or more of them.

An applied amount of the electron-donating dopants differs dependent on the types of the materials, but it is preferably 0.1% by weight to 99% by weight with respect to an electron-transport layer material, more preferably 1.0% by weight to 80% by weight, and particularly preferably 2.0% by weight to 70% by weight.

A thickness of the electron injection layer and the electron-transport layer is preferably 500 nm or less, respectively in view of decreasing driving voltage. The thickness of the electron-transport layer is preferably 1 nm to 500 nm, more preferably is 5 nm to 200 nm, and particularly preferably is 10 nm to 100 nm. The thickness of the electron-injection layer is preferably 0.1 nm to 200 nm, more preferably is 0.2 nm to 100 nm, and particularly preferably is 0.5 nm to 50 nm.

The electron injection layer and the electron-transport layer may have either a monolayered structure comprising one or two or more of the above-mentioned materials, or a multilayer structure composed of plural layers of a homogeneous composition or a heterogeneous composition.

(Positive Hole-Blocking Layer)

A positive hole-blocking layer is a layer having a function to prevent the positive holes transported from the anode to the light-emitting layer from passing through to the cathode side. According to the present invention, a positive hole-blocking layer may be provided as an organic compound layer adjacent to the light-emitting layer on the cathode side.

The positive hole-blocking layer is not particularly limited, but specifically, it may contain an aluminum complex such as BAlq, a triazole derivative, a phenanthroline derivative such as BCP, or the like.

It is preferred that a thickness of the positive hole-blocking layer is preferably 1 nm to 500 nm, more preferably it is 5 nm to 200 nm, and further preferably it is 10 nm to 100 nm.

The positive hole-blocking layer may have either a mono-layered structure comprising one or two or more of the above-mentioned materials, or a multilayer structure composed of plural layers of a homogeneous composition or a heterogeneous composition.

(Electron-Blocking Layer)

An electron-blocking layer is a layer having a function to prevent the electron transported from the cathode to the light-emitting layer from passing through to the anode side. According to the present invention, a electron-blocking layer may be provided as an organic compound layer adjacent to the light-emitting layer on the anode side.

Specific examples of the electron-blocking layer include compounds explained above as a positive hole-transporting material.

It is preferred that a thickness of the electron-blocking layer is preferably 1 nm to 500 nm, more preferably it is 5 nm to 200 nm, and further preferably it is 10 mm to 100 nm.

The electron-blocking layer may have either a monolayered structure comprising one or two or more of the above-mentioned materials, or a multilayer structure composed of plural layers of a homogeneous composition or a heterogeneous composition.

(Protective Layer)

According to the present invention, the whole organic EL element may be protected by a protective layer.

A material contained in the protective layer may be one having a function to prevent penetration of substances such as moisture and oxygen, which accelerate deterioration of the device, into the device.

Specific examples thereof include metals such as In, Sn, Pb, Au, Cu, Ag, Al, Ti, Ni and the like; metal oxides such as MgO, SiO, SiO₂, Al₂O₃, GeO, NiO, CaO, BaO, Fe₂O₃, Y₂O₃, TiO₂ and the like; metal nitrides such as SiNₓ, SiNₓO_{y} and the like; metal fluorides such as MgF₂, LiF, AlF₃, CaF₂ and the like; polyethylene; polypropylene; polymethylmethacrylate; polyimide; polyurea; polytetrafluoroethylene; polychlorotrifluoroethylene; polydichlorodifluoroethylene; a copolymer of chlorotrifluoroethylene and dichlorodifluoroethylene; copolymers obtained by copolymerizing a monomer mixture containing tetrafluoroethylene and at least one comonomer; fluorine-containing copolymers each having a cyclic structure in the copolymerization main chain; water-absorbing materials each having a coefficient of water absorption of 1% or more; moisture permeation preventive substances each having a coefficient of water absorption of 0.1% or less; and the like.

There is no particular limitation as to a method for forming the protective layer. For instance, a vacuum deposition method, a sputtering method, a reactive sputtering method, an MBE (molecular beam epitaxial) method, a cluster ion beam method, an ion plating method, a plasma polymerization method (high-frequency excitation ion plating method), a plasma CVD method, a laser CVD method, a thermal CVD method, a gas source CVD method, a coating method, a printing method, or a transfer method may be applied.

(Sealing)

The whole organic electroluminescence element of the present invention may be sealed with a sealing cap.

Furthermore, a moisture absorbent or an inert liquid may be used to seal a space defined between the sealing cap and the luminescent device. Although the moisture absorbent is not particularly limited, specific examples thereof include barium oxide, sodium oxide, potassium oxide, calcium oxide, sodium sulfate, calcium sulfate, magnesium sulfate, phosphorus pentoxide, calcium chloride, magnesium chloride, copper chloride, cesium fluoride, niobium fluoride, calcium bromide, vanadium bromide, molecular sieve, zeolite, magnesium oxide and the like. Although the inert liquid is not particularly limited, specific examples thereof include paraffins; liquid paraffins; fluorine-based solvents such as perfluoroalkanes, perfluoroamines, perfluoroethers and the like; chlorine-based solvents; silicone oils; and the like.

(Driving of Element)

In the organic electroluminescence element of the present invention, when a DC (AC components may be contained as needed) voltage (usually 2 volts to 15 volts) or DC is applied across the anode and the cathode, luminescence can be obtained.

For the driving method of the organic electroluminescence element of the present invention, driving methods described in Japanese Patent Application Laid-Open (JP-A) Nos. 2-148687, 6-301355, 5-29080, 7-134558, 8-234685, and 8-241047; Japanese Patent No. 2784615, U.S. Pat. Nos. 5,828,429 and 6,023,308 are applicable.

In the organic EL element of the present invention, the light-extraction efficiency can be improved by various known methods. It is possible to elevate the light-extraction efficiency and to improve the external quantum efficiency, for example, by modifying the surface shape of the substrate (for example by forming fine irregularity pattern), by controlling the refractive index of the substrate, the ITO layer and/or the organic layer, or by controlling the thickness of the substrate, the ITO layer and/or the organic layer.

The organic electroluminescence element of the present invention may have a so-called top-emission configuration in which the light emission is extracted from the anode side.

(Application of the Organic Electroluminescence Element of the Present Invention)

The organic electroluminescence element of the present invention can be appropriately used for indicating elements, displays, backlights, electronic photographs, illumination light sources, recording light sources, exposure light sources, reading light sources, signages, advertising displays, interior accessories, optical communications and the like.

### EXAMPLES

In the following, examples of the organic electroluminescence device of the present invention will be described, but it should be noted that the present invention is not limited to these examples.

### Example 1

### 1. Preparation of the Organic Electroluminescent Element

(Preparation of Organic EL Element No. 1 of the Invention)

A 2.5 cm square ITO attached glass substrate having a 0.5 mm thickness (manufactured by Geomatec Co., Ltd.; surface resistance: 10Ω/□) was placed in a washing container to apply ultrasonic cleaning in 2-propanol, and then, UV-ozone treatment was applied for 30 minutes. On the transparent anode, the following layers were deposited in accordance with a vacuum deposition method. In the examples of the present invention, a deposition rate was 0.2 nm/second, unless otherwise specified, wherein the deposition rate was measured by the use of a quartz oscillator. The thicknesses of layers described below were also measured by using the quartz oscillator.

—Positive Hole-Injection Layer—

2-TNATA and F4-TCNQ were co-evaporated so as to an amount of F4-TCNQ to be 0.3% by weight with respect to the 2-TNATA. The thickness was 160 nm.

—Positive Hole-Transport Layer—

On the positive hole-injection layer, α-NPD was evaporated at a thickness of 10 nm.

—Light-Emitting Layer—

Ternary co-evaporation was conducted in such that host material mCP, tri-dentate platinum complex A-1 at an amount of 6% by weight, and metal-free compound B-1 at an amount of 10% by weight with respect to the total materials in the light-emitting layer. The thickness of the light-emitting layer was 40 nm.

—Electron-Transport Layer—

BAlq was deposited at a thickness of 40 nm.

—Electron Injection Layer—

Lithium fluoride was deposited at a thickness of 0.5 nm.

—Cathode—

On the resulting layers, a patterned mask (mask by which the light emitting region becomes 2 mm×2 mm) was disposed, and metal aluminum was deposited thereon with a 100 nm thickness to obtain a cathode.

The prepared lamination body was placed in a globe box whose contents were replaced by argon gas, and it was sealed by the use of a sealing cap made of stainless steel and a UV curable adhesive (trade name: XNR5516HV, manufactured by Nagase-Ciba Co., Ltd.).

(Preparation of Comparative Organic EL Element)

Comparative element No. 1: comparative element No. 1 was prepared in a similar manner as in the preparation of organic EL element No. 1 of the invention, except that the composition of the light-emitting layer was replaced by the following compositions in the organic EL element No. 1 of the invention.

Light-emitting layer: co-evaporation was conducted in such that host material mCP and tri-dentate platinum complex A-1 at an amount of 6% by weight with respect to the host materials. The thickness of the light-emitting layer was 40 nm.

(Preparation of Comparative Organic EL Element No. 2-9, and Inventive Organic EL Element No. 2-9)

Comparative organic EL element No. 2-9, and inventive organic EL element No. 2-9 were prepared in a similar manner as in the preparation of comparative organic EL element No. 1 and inventive organic EL element No. 1, except that the composition of host material, multi-dentate metal complex and metal-free compound were changed as shown in Table 1.

TABLE 1

| | | Metal Complex | | Metal-free Compound | |
|---|---|---|---|---|---|
| | | | Addition Amount | | Addition Amount |
| | Host | Compound | (% by weight to | Compound | (% by weight to |
| Element No. | Material | No. | Host Material) | No. | Host Material) |
| Comparative No. 1 | mCP | A-1 | 6 | — | — |
| Inventive Element No. | mCP | A-1 | 6 | B-1 | 10 |
| Comparative No. 2 | mCP | A-2 | 8 | — | — |
| Inventive Element No. | mCP | A-2 | 8 | B-2 | 10 |
| Comparative No. 3 | mCP | A-3 | 4 | — | — |
| Inventive Element No. | mCP | A-3 | 4 | B-3 | 8 |
| Comparative No. 4 | mCP | A-7 | 6 | — | — |
| Inventive Element No. | mCP | A-7 | 6 | B-7 | 10 |
| Comparative No. 5 | mCP | A-9 | 6 | — | — |
| Inventive Element No. | mCP | A-9 | 6 | B-9 | 10 |
| Comparative No. 6 | mCP | A-12 | 15 | — | — |
| Inventive Element No. | mCP | A-12 | 15 | B-12 | 20 |
| Comparative No. 7 | mCP | A-14 | 6 | — | — |
| Inventive Element No. | mCP | A-14 | 6 | B-14 | 6 |
| Comparative No. 8 | mCP | A-15 | 8 | — | — |
| Inventive Element No. | mCP | A-15 | 8 | B-15 | 8 |
| Comparative No. 9 | mCP | A-16 | 6 | — | — |
| Inventive Element No. | mCP | A-16 | 6 | B-16 | 10 |

Structures of the compounds used in the above-described luminescent devices are shown below. The structures of metal complexes and metal-free compounds used in the examples are shown in each explanation of the compounds in the description. 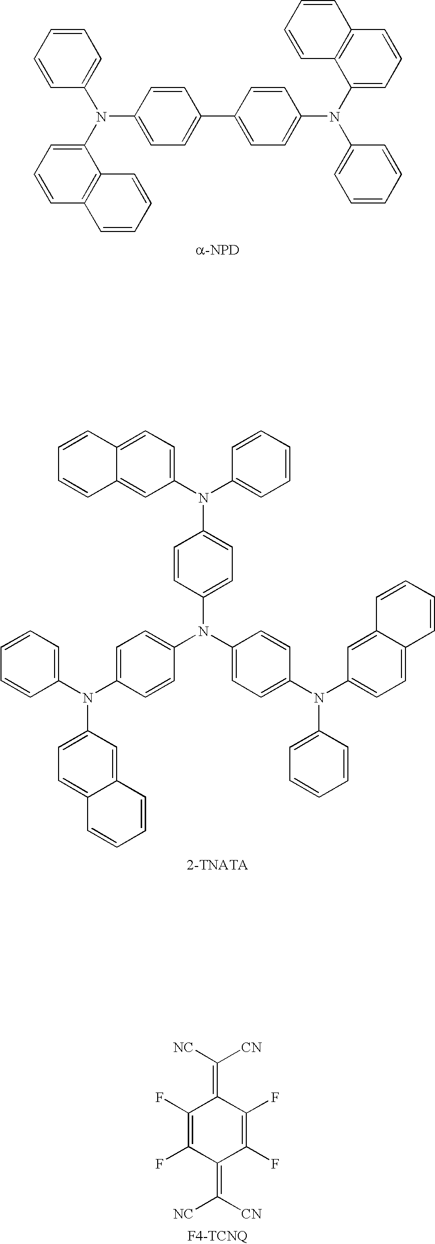 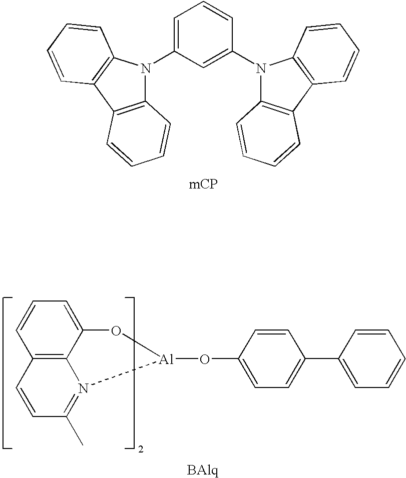
<Evaluation of Performance of Organic EL Element>
1) External Quantum Efficiency

A DC voltage was applied, using a Source Measure Unit 2400 manufactured by Toyo TECHNICA Corp., to each device to thereby cause light emission. The brightness of luminance was measured using a Brightness Meter BM-8 manufacture to Topcon Corp. Light emission spectra and light emission wavelengths were measured using a Spectrum Analyzer PMA-11, manufactured by Hamamatsu Photonics K.K. Based on these values, an external quantum efficiency at a luminance of 500 cd/m² was calculated by a brightness conversion method.

2) Driving Durability: Half-Life Period of Brightness

The half-life period of brightness of luminance was used as an index for the driving durability. An initial brightness of luminance were adjusted to be 300 cd/m² for blue light emission element, 2000 cd/m² for green light emission element, and 1000 cd/m² for rede light emission element, and were driven continuously to reach at half value thereof.

The obtained results are summarized in Table 2.

TABLE 2

| | | External | |
|---|---|---|---|
| | | Quantum | Half-Life Period |
| | Iluminance | Efficiency | of Bright- |
| Element No. | Color | (%) | ness (h) |
| Comparative No. 1 | Blue | 7.3 | 1000 |
| Inventive Element No. 1 | Blue | 8.2 | 1200 |
| Comparative No. 2 | Light Blue | 8.5 | 1600 |
| Inventive Element No. 2 | Light Blue | 8.9 | 2000 |
| Comparative No. 3 | Green | 12.3 | 800 |
| Inventive Element No. 3 | Green | 14.5 | 1100 |
| Comparative No. 4 | Red | 8.2 | 1400 |
| Inventive Element No. 4 | Red | 8.2 | 1700 |
| Comparative No. 5 | Green | 13.3 | 3000 |
| Inventive Element No. 5 | Green | 13.6 | 3900 |
| Comparative No. 6 | Blue | 7.2 | 300 |
| Inventive Element No. 6 | Blue | 7.8 | 600 |
| Comparative No. 7 | Green | 10.1 | 400 |
| Inventive Element No. 7 | Green | 12.1 | 450 |
| Comparative No. 8 | Green | 9.2 | 600 |
| Inventive Element No. 8 | Green | 9.3 | 700 |
| Comparative No. 9 | Blue | 6.2 | 800 |
| Inventive Element No. 9 | Blue | 6.9 | 1000 |

As will be apparent from the above-described results, the elements of the present invention, in comparison with the comparative elements, exhibited a higher light emitting efficiency and an excellent durability at unexpectedly large extent.

What is claimed is:

1. An organic electroluminescent element comprising at least one organic layer including a light-emitting layer between a pair of electrodes, wherein the light-emitting layer includes a metal complex having a tri-dentate or higher multi-dentate ligand, and a metal-free compound capable of giving a three or higher coordination with the same metal element as a central metal of the metal complex.

2. The organic electroluminescent element according to claim 1, wherein the coordination number of the metal-free compound is same as the coordination number of the metal complex.

3. The organic electroluminescent element according to claim 2, wherein the metal-free compound has, as a partial structure, a chemical structure in which metal is removed from the metal complex.

4. The organic electroluminescent element according to claim 1, wherein the metal-free compound is a linear compound.

5. The organic electroluminescent element according to claim 4, wherein the metal complex is a compound represented by the following formula LA1, and the linear compound is a compound represented by the following formula LA2: 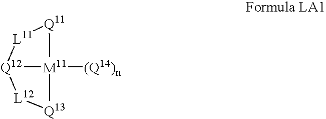
wherein M¹¹ represents a metal ion; Q¹¹ to Q¹⁴ each independently represent a substituent which coordinates with M¹¹; L¹¹ and L¹² each independently represent a single bond or a linking group; and n represents an integer of from 0 to 4; 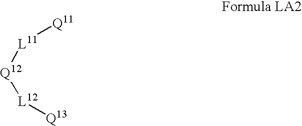
wherein Q¹¹ to Q¹³ and L¹¹ and L¹² are each a group having the same skeleton structure as that of the formula LA1, and may independently have a substituent.

6. The organic electroluminescent element according to claim 4, wherein the metal complex is a compound represented by the following formula LA3, and the linear compound is a compound represented by the following formula LA4: 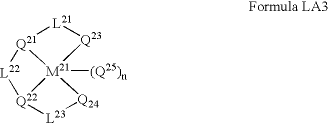
wherein M²¹ represents a metal ion; Q²¹ to Q²⁵ each independently represent a substitutent which coordinates with M²¹; L²¹ to L²³ each independently represent a single bond or a linking group; and n represents an integer of from 0 to 4; 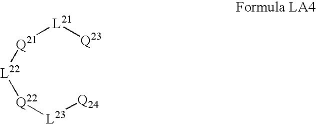
wherein Q²¹ to Q²⁴ and L²¹ to L²³ are each a group having the same skeleton structure as that of the formula LA3, and may independently have a substituent.

7. The organic electroluminescent element according to claim 4, wherein the metal complex is a compound represented by the following formula LA5, and the linear compound is a compound represented by the following formula LA6: 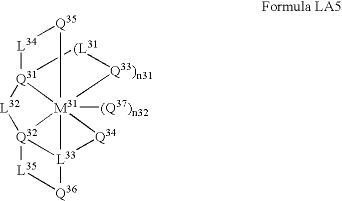
wherein M³¹ represents a metal ion; Q³¹ to Q³⁷ each independently represent a substituent which coordinates with M³¹; L³¹ to L³⁵ each independently represent a single bond or a linking group; and n31 and n32 each independently represent an integer of from 0 to 4; 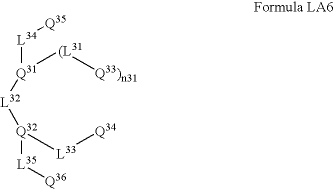
wherein Q³¹ to Q³⁶ and L³¹ to L³⁵ are each a group having the same skeleton structure as that of the formula LA5, and may independently have a substituent.

8. The organic electroluminescent element according to claim 4, wherein the metal complex is a compound represented by the following formula LA7, and the linear compound is a compound represented by the following formula LA8: 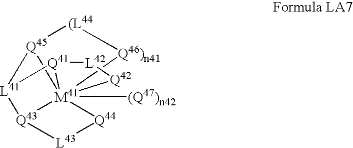
wherein M⁴¹ represents a metal ion; Q⁴¹ to Q⁴⁷ each independently represent a substituent which coordinates with M⁴¹; L⁴¹ to L⁴⁴ each independently represent a single bond or a linking group; and n41 and n42 each independently represent an integer of from 0 to 4; 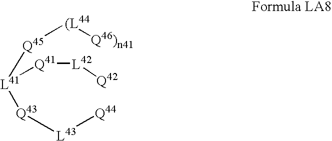
wherein Q⁴¹ to Q⁴⁶ and L⁴¹ to L⁴⁴ are each a group having the same skeleton structure as that of the formula LA7, and may independently have a substituent.
